(19) United States
(12) Patent Application Publication
(10) Pub. No.: US 2019/0334535 A1
(43) Pub. Date: Oct. 31, 2019

(54) ATOMIC OSCILLATOR AND FREQUENCY SIGNAL GENERATION SYSTEM

(71) Applicant: Seiko Epson Corporation, Tokyo (JP)

(72) Inventor: Katsuhiko MAKI, Chino (JP)

(21) Appl. No.: 16/395,390

(22) Filed: Apr. 26, 2019

(30) Foreign Application Priority Data
Apr. 27, 2018 (JP) 2018-087839

(51) Int. Cl. H03L 7/26; G06F 1/10; G06F 1/12

(52) U.S. Cl. CPC H03L 7/26; G06F 1/12; G06F 1/10

(57) ABSTRACT

An atomic oscillator includes a light emitting element, an atomic cell that has a first chamber in which alkali metal atoms in a gas state are contained and through which a light from the light emitting element passes, a second chamber in which alkali metal atoms in a liquid state are contained, and a passage connecting the first chamber and the second chamber to each other, and a light receiving element that receives the light passing through the first chamber, in which the light receiving element is disposed between the first chamber and the second chamber.

The present application is based on and claims priority from JP Application Serial Number 2018-087839, filed Apr. 27, 2018, the disclosure of which is hereby incorporated by reference herein in its entirety.

### BACKGROUND

### 1. Technical Field

The present disclosure relates to an atomic oscillator and a frequency signal generation system.

### 2. Related Art

As an oscillator having high precision oscillation characteristics in the long term, an atomic oscillator oscillating based on energy transition of alkali metal atoms such as cesium is known. The atomic oscillator includes a light source, an atomic cell in which alkali metal atoms such as cesium or the like are sealed, and a light receiving element for receiving a light passing through the atomic cell.

For example, JP-A-2015-53304 discloses an atomic oscillator including an atomic cell in which a gas container containing metal atoms in a gas state and a metal accumulator containing metal atoms in a liquid or solid state. Generally, the temperature of the metal accumulator is lower than the temperature of the gas container.

In the atomic oscillator as described above, it is preferable that the temperature of one of the gas container and the metal accumulator is not easily affected by the other. If the temperature of one of the gas container and the metal accumulator is likely to affect the other, it becomes difficult to control the state of the alkali metal atoms contained in the atomic cell.

### SUMMARY

An atomic oscillator according to an aspect of the present disclosure includes a light emitting element that emits a light, an atomic cell that has a first chamber in which alkali metal atoms in a gas state are contained and through which the light emitted from the light emitting element passes, a second chamber in which alkali metal atoms in a liquid state are contained, and a passage connecting the first chamber and the second chamber to each other, and a light receiving element that receives the light passing through the first chamber, in which the light receiving element is disposed between the first chamber and the second chamber.

In the atomic oscillator according to the aspect of the present disclosure, the light emitting element may be disposed on a side opposite to the light receiving element with respect to the first chamber.

An atomic oscillator according to another aspect of the present disclosure includes a light emitting element that emits a light, an atomic cell that has a first chamber in which alkali metal atoms in a gas state are contained and through which the light emitted from the light emitting element passes, a second chamber in which alkali metal atoms in a liquid state are contained, and a passage connecting the first chamber and the second chamber to each other, and alight receiving element that receives the light passing through the first chamber, in which the light emitting element is disposed between the first chamber and the second chamber.

In the atomic oscillator according to the aspect of the present disclosure, the light receiving element may be disposed on a side opposite to the light emitting element with respect to the first chamber.

The atomic oscillator according to the aspect of the present disclosure may include a first holding member and a second holding member that hold the atomic cell, in which a temperature of the first holding member may be higher than a temperature of the second holding member, among inner surfaces intersecting an axis along a direction in which the light emitted from the light emitting element advances, apart of the atomic cell positioned between two inner surfaces of the atomic cell having the longest distance therebetween along the axis may have a first part that is in contact with the first holding member and a second part that is in contact with the second holding member, and in the part, a length along the axis of the first part may be larger than a sum of a length along the axis of the first chamber and a length along the axis of the passage, and a length along the axis of the second part may be smaller than a length along the axis of the second chamber.

The atomic oscillator according to the aspect of the present disclosure may include a first holding member and a second holding member that hold the atomic cell, in which a temperature of the first holding member may be higher than a temperature of the second holding member, among inner surfaces intersecting an axis along a direction in which the light emitted from the light emitting element advances, apart of the atomic cell positioned between two inner surfaces of the atomic cell having the longest distance therebetween along the axis may have a first part that is in contact with the first holding member and a second part that is in contact with the second holding member, and in the part, a length along the axis of the first part may be smaller than a length along the axis of the first chamber, and a length along the axis of the second part maybe larger than a sum of a length along the axis of the second chamber and a length along the axis of the passage.

In the atomic oscillator according to the aspect of the present disclosure, the first chamber may have a window through which the light emitted from the light emitting element passes, and the passage may be connected to the window.

In the atomic oscillator according to the aspect of the present disclosure, a distance between two areas of an inner surface intersecting a first axis along a direction orthogonal to a direction in which the light emitted from the light emitting element advances, in the first chamber and a distance between two areas of an inner surface intersecting a second axis parallel to the first axis, in the second chamber may be larger than a distance between two areas of an inner surface intersecting a third axis parallel to the first axis, in the passage.

In the atomic oscillator according to the aspect of the present disclosure, a distance between two areas of an inner surface intersecting a first axis along a direction orthogonal to a direction in which the light emitted from the light emitting element advances, in the first chamber may be larger than a distance between two areas of an inner surface intersecting a second axis parallel to the first axis, in the second chamber, and the distance between the two areas of an inner surface intersecting the second axis may be the same as a distance between two areas of an inner surface intersecting a third axis parallel to the first axis, in the passage.

A frequency signal generation system according to another aspect of the present disclosure includes an atomic oscillator, in which the oscillator includes a light emitting element that emits a light, an atomic cell that has a first chamber in which alkali metal atoms in a gas state are contained and through which the light emitted from the light emitting element passes, a second chamber in which alkali metal atoms in a liquid state are contained, and a passage connecting the first chamber and the second chamber to each other, and a light receiving element that receives the light passing through the first chamber, in which the light receiving element is disposed between the first chamber and the second chamber.

A frequency signal generation system according to another aspect of the present disclosure includes an atomic oscillator, in which the atomic oscillator includes a light emitting element that emits a light, an atomic cell that has a first chamber in which alkali metal atoms in a gas state are contained and through which the light emitted from the light emitting element passes, a second chamber in which alkali metal atoms in a liquid state are contained, and a passage connecting the first chamber and the second chamber to each other, and a light receiving element that receives the light passing through the first chamber, in which the light emitting element is disposed between the first chamber and the second chamber.

### BRIEF DESCRIPTION OF THE DRAWINGS

FIG. 1 is a schematic view showing an atomic oscillator according to a first embodiment.

FIG. 2 is a cross-sectional view schematically showing the atomic oscillator according to the first embodiment.

FIG. 3 is a cross-sectional view schematically showing the atomic oscillator according to the first embodiment.

FIG. 4 is a cross-sectional view schematically showing an atomic cell unit of the atomic oscillator according to the first embodiment.

FIG. 5 is a perspective view schematically showing an atomic cell of the atomic oscillator according to the first embodiment.

FIG. 6 is a cross-sectional view schematically showing an atomic cell unit of the atomic oscillator according to a first modification example of the first embodiment.

FIG. 7 is a cross-sectional view schematically showing an atomic cell of the atomic oscillator according to a second modification example of the first embodiment.

FIG. 8 is a perspective view schematically showing the atomic cell of the atomic oscillator according to the second modification example of the first embodiment.

FIG. 9 is a cross-sectional view schematically showing an atomic cell unit of the atomic oscillator according to a second embodiment.

FIG. 10 is a cross-sectional view schematically showing an atomic cell unit of the atomic oscillator according to a modification example of the second embodiment.

FIG. 11 is a schematic configuration view showing a frequency signal generation system according to a third embodiment.

### DESCRIPTION OF EXEMPLARY EMBODIMENTS

Hereinafter, preferred embodiments of the present disclosure will be described in detail with reference to the drawings. Note that the embodiments described below do not unduly limit the contents of the present disclosure described in the appended claims. Also, not all of the configurations described below are necessarily essential components of the present disclosure.

1. First Embodiment

1.1. Atomic Oscillator

1.1.1 Outline

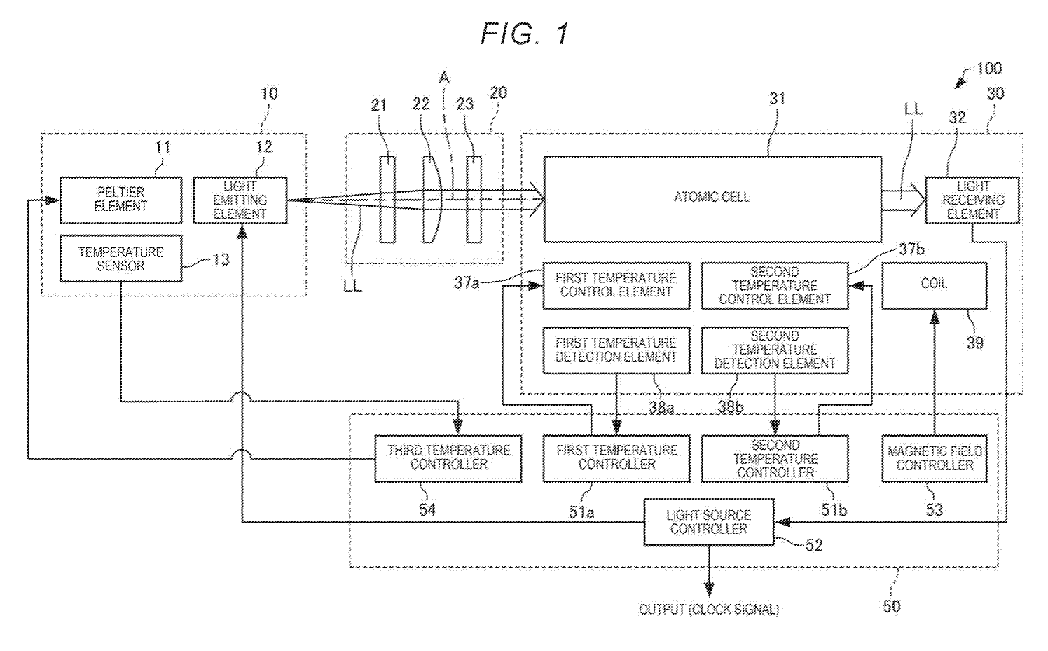

First, an atomic oscillator according to a first embodiment will be described with reference to the drawings. FIG. 1 is a schematic view showing an atomic oscillator 100 according to the first embodiment.

The atomic oscillator 100 is an atomic oscillator using a quantum interference effect (CPT: Coherent Population Trapping) in which, when alkali metal atoms are simultaneously irradiated with two resonance lights of specific wavelengths different each other, a phenomenon occurs where the two resonant lights are transmitted without being absorbed by the alkali metal atoms. Note that the phenomenon due to the quantum interference effect is also referred to as an electromagnetically induced transparency (EIT) phenomenon. Further, the atomic oscillator according to the present disclosure may be an atomic oscillator using a double resonance phenomenon by a light and a microwave.

As shown in FIG. 1, the atomic oscillator 100 includes a light source unit 10, an optical system unit 20, an atomic cell unit 30, and a control unit 50 for controlling the light source unit 10 and the atomic cell unit 30. Hereinafter, an outline of the atomic oscillator 100 will be described first.

The light source unit 10 has a Peltier element 11, a light emitting element 12, and a temperature sensor 13.

The light emitting element 12 emits a linearly polarized light LL containing two kinds of lights having different frequencies. The light emitting element 12 is, for example, a vertical cavity surface emitting laser (VCSEL) . The temperature sensor 13 detects the temperature of the light emitting element 12. The Peltier element 11 controls the temperature of the light emitting element 12.

The optical system unit 20 is disposed between the light source unit 10 and the atomic cell unit 30. The optical system unit 20 has a neutral density filter 21, a lens 22, and a quarter wavelength plate 23.

The neutral density filter 21 reduces the intensity of the light LL emitted from the light emitting element 12. The lens 22 adjusts a radiation angle of the light LL. Specifically, the lens 22 makes the light LL into a parallel light. The quarter wavelength plate 23 converts the two kinds of lights having different frequencies included in the light LL from a linearly polarized light to a circularly polarized light.

The atomic cell unit 30 includes an atomic cell 31, a light receiving element 32, a first temperature control element 37a, a second temperature control element 37b, a first temperature detection element 38a, a second temperature detection element 38b, and a coil 39.

The atomic cell 31 contains alkali metal atoms. The alkali metal atom has an energy level of a three-level system configured with two ground levels different from each other and an excitation level. The light LL emitted from the light emitting element 12 is incident on the atomic cell 31 via the neutral density filter 21, the lens 22, and the quarter wavelength plate 23.

The light receiving element 32 receives and detects the light LL passed through the atomic cell 31. The light receiving element 32 is, for example, a photodiode.

The first temperature control element 37a heats the alkali metal atoms contained in the atomic cell 31 and brings at least a part of the alkali metal atoms into a gas state. The first temperature control element 37a is, for example, a heater. The first temperature detection element 38a detects the temperature of the atomic cell 31. The second temperature control element 37b, for example, heats the atomic cell 31 to a temperature lower than the temperature of the first temperature control element 37a. The second temperature control element 37b is, for example, a Peltier element. The second temperature detection element 38b detects the temperature of the atomic cell 31. The temperature detection elements 38a and 38b, and the temperature sensor 13 are, for example, thermistors or the like.

The coil 39 applies a magnetic field in a predetermined direction to the alkali metal atoms contained in the atomic cell 31 and Zeeman splits an energy level of the alkali metal atoms. When the alkali metal atoms are irradiated with a pair of circularly polarized resonance light in a state where the alkali metal atoms are Zeeman split, the number of alkali metal atoms having a desired energy level is relatively larger than the number of alkali metal atoms having other energy levels among a plurality of levels of the alkali metal atoms that are Zeeman split. Therefore, the number of atoms that develops a desired EIT phenomenon increases, and a desired EIT signal increases. As a result, the oscillation characteristics of the atomic oscillator 100 can be improved.

The control unit 50 includes a first temperature controller 51a, a second temperature controller 51b, a light source controller 52, a magnetic field controller 53, and a third temperature controller 54. Based on a detection result of the first temperature detection element 38a, the first temperature controller 51a controls carrying of electricity to the first temperature control element 37a so that an inside of the atomic cell 31 becomes a desired temperature. Based on a detection result of the second temperature detection element 38b, the second temperature controller 51b controls carrying of electricity to the second temperature control element 37b so that the inside of the atomic cell 31 becomes a desired temperature. The magnetic field controller 53 controls carrying of electricity to the coil 39 so that the magnetic field generated by the coil 39 is constant. Based on a detection result of the temperature sensor 13, the third temperature controller 54 controls carrying of electricity to the Peltier element 11 so that the temperature of the light emitting element 12 becomes a desired temperature.

Based on a detection result of the light receiving element 32, the light source controller 52 controls frequencies of two kinds of lights included in the light LL emitted from the light emitting element 12 so that the EIT phenomenon occurs. Here, the EIT phenomenon occurs when the two kinds of lights become a pair of resonant lights of a frequency difference corresponding to an energy difference between two ground levels of the alkali metal atoms contained in the atomic cell 31. The light source controller 52 includes a voltage controlled oscillator (not shown) in which an oscillation frequency is controlled so as to be stabilized in synchronization with the control of the frequencies of the two kinds of lights, and outputs an output signal of the voltage controlled oscillator (VOC) as an output signal (clock signal) of the atomic oscillator 100.

1.1.2. Specific Configuration

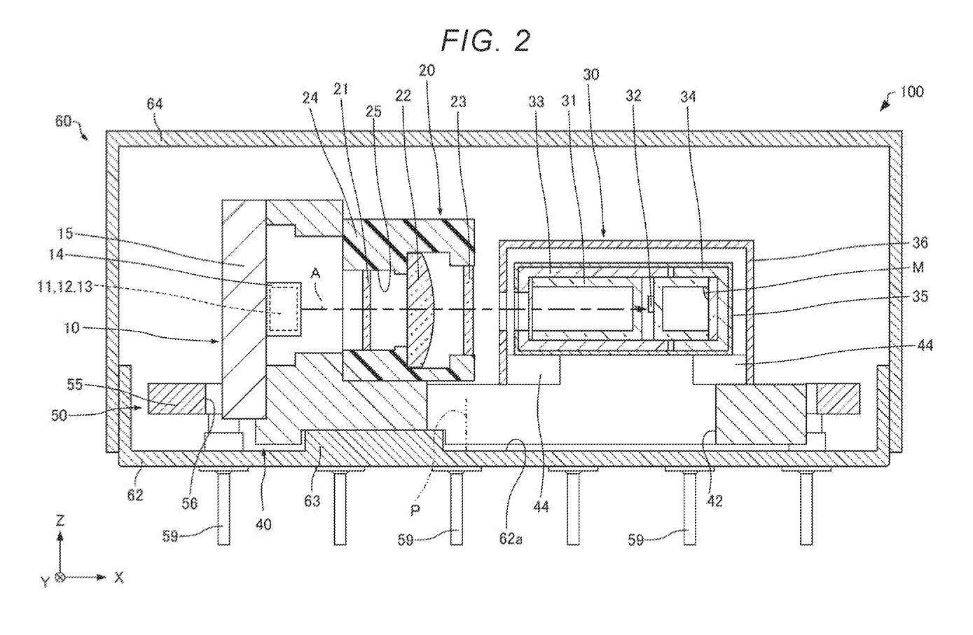

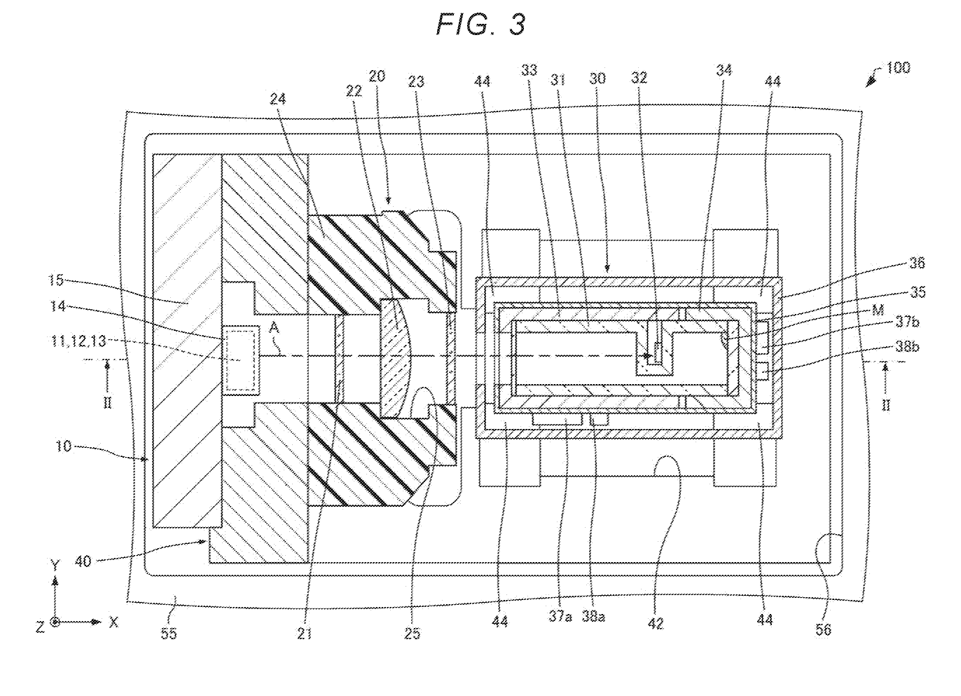

Next, a specific configuration of the atomic oscillator 100 will be described. FIGS. 2 and 3 are cross-sectional views schematically showing the atomic oscillator 100. Note that FIG. 2 is a cross-sectional view taken along the line II-II in FIG. 3. In FIGS. 2 and 3, and FIG. 4 to be described later, X, Y, and Z axes are shown as three axes orthogonal to each other.

As shown in FIGS. 2 and 3, the atomic oscillator 100 includes the light source unit 10, the optical system unit 20, the atomic cell unit 30, a supporting member 40, the control unit 50, and an outer container 60.

Here, the Z axis is an axis along the perpendicular P of an inner surface 62a of a base body 62 of the outer container 60, and the Z axis+direction is a direction from the inner surface 62a to a component disposed on the inner surface 62a. The X axis is an axis along the light emitted from the light source unit 10 and the X axis+direction is a direction in which the light emitted from the light source unit 10 advances. The Y axis is an axis perpendicular to the X axis and the Z axis and the Y axis+direction is a direction from the front to the back when the Z axis+direction is up and the X axis+direction is directed to the right.

The light source unit 10 is disposed on the supporting member 40. The light source unit 10 includes the Peltier element 11, the light emitting element 12, the temperature sensor 13, a light source container 14 which contains the Peltier element 11, the light emitting element 12, and the temperature sensor 13, and a light source substrate 15 on which the light source container 14 is disposed. The light source substrate 15 is, for example, fixed to the supporting member 40. The Peltier element 11, the light emitting element 12, and the temperature sensor 13 are electrically connected to the control unit 50.

The optical system unit 20 is disposed on the supporting member 40. The optical system unit 20 has the neutral density filter 21, the lens 22, the quarter wavelength plate 23, and a holder 24 which holds the neutral density filter 21, the lens 22, and the quarter wavelength plate 23. The holder 24 is, for example, fixed to the supporting member 40.

The holder 24 is provided with a through hole 25. The through hole 25 is a passing area of the light LL. In the through hole 25, the neutral density filter 21, the lens 22, and the quarter wavelength plate 23 are arranged in the order from the light source unit 10 side.

The atomic cell unit 30 includes the atomic cell 31, the light receiving element 32, a first holding member 33, a second holding member 34, a first atomic cell container 35, a second atomic cell container 36, the first temperature control element 37a, the second temperature control element 37b, the first temperature detection element 38a, and the second temperature detection element 38b. The detailed configuration of the atomic cell unit 30 will be described later.

Note that, although not shown in FIGS. 2 and 3, for example, the coil 39 may be a solenoid type coil wound around the outer circumference of the atomic cell 31, or a pair of Helmholtz type coils facing each other via the atomic cell 31. The coil 39 generates a magnetic field in the atomic cell 31 in a direction along an optical axis A of the light. Thereby, a gap between different degenerate energy levels of the alkali metal atoms contained in the atomic cell 31 can be expanded by Zeeman split, a resolution can be improved, and a line width of the EIT signal can be reduced.

As shown in FIG. 2, the supporting member 40 is cantilevered and fixed to the base body 62 of the outer container 60. In the illustrated example, the supporting member 40 is fixed to a pedestal portion 63 of the base body 62. A material of the supporting members 40 is, for example, an aluminum, or a copper. The supporting member 40 may be a carbon sheet using a carbon fiber.

The supporting member 40 is provided with a through hole 42. The through hole 42 passes through the supporting member 40 along the Z axis direction. When viewed from the Z axis direction, the atomic cell unit 30 is disposed so as to overlap with the through hole 42. The atomic cell unit 30 is supported by the supporting member 40. In the illustrated example, the first atomic cell container 35 is supported by the supporting member 40 via a spacer 44. A material of the spacer 44 is, for example, a resin such as an engineering plastic, a liquid crystal polymer (LCP) resin, a polyether ether ketone (PEEK), or the like.

The control unit 50 has a circuit substrate 55. The circuit substrate 55 is fixed to the base body 62 of the outer container 60 via a plurality of lead pins 59. An integrated circuit (IC) chip (not shown) is disposed on the circuit substrate 55, and the IC chip functions as the temperature controllers 51a, 51b, and 54, the light source controller 52, and the magnetic field controller 53. The IC chip is electrically connected to the light source unit 10 and the atomic cell unit 30. The circuit substrate 55 is provided with a through hole 56 through which the supporting member 40 is inserted.

The outer container 60 contains the light source unit 10, the optical system unit 20, the atomic cell unit 30, the supporting member 40, and the control unit 50. The outer container 60 has a base body 62 and a lid body 64 that is a separate body from the base body 62.

A material of the outer container 60 is, for example, a permalloy, a silicon iron, or the like. By using such a material, the outer container 60 can shield a magnetic field from the outside. As a result, the first atomic cell container 35 can inhibit the alkali metal atoms in the atomic cell 31 from being influenced by the magnetic field from the outside and stabilize the oscillation characteristics of the atomic oscillator 100. The inside of the outer container 60 may be a nitrogen atmosphere or a vacuum.

1.1.3. Structure of Atomic Cell Unit

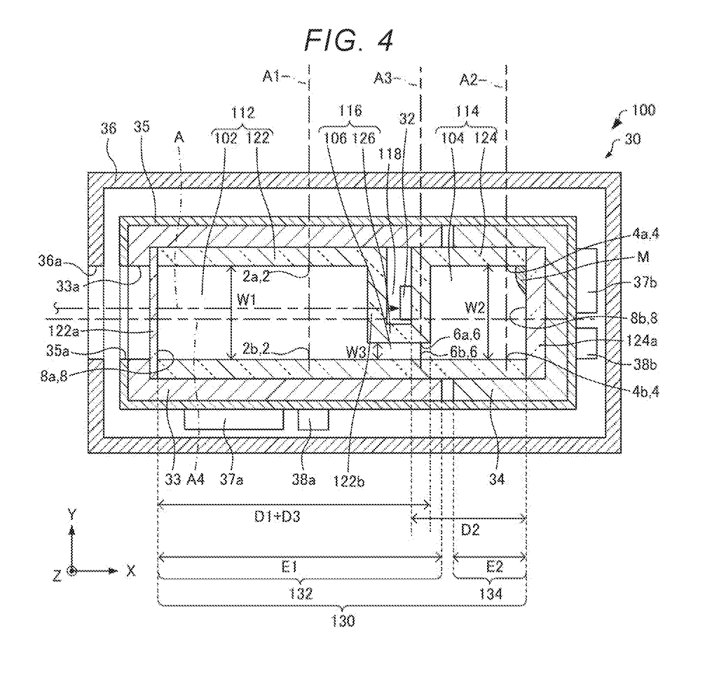

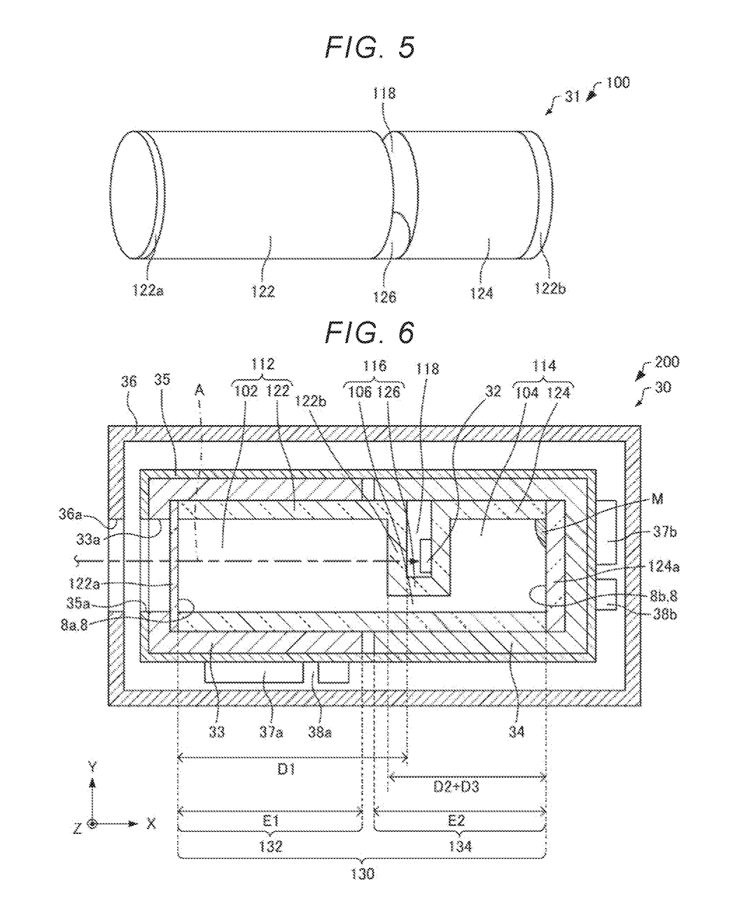

Next, a specific configuration of the atomic cell unit 30 will be described. FIG. 4 is a cross-sectional view schematically showing the atomic cell unit 30. FIG. 5 is a perspective view schematically showing the atomic cell 31 of the atomic cell unit 30.

As shown in FIGS. 4 and 5, the atomic cell unit 30 includes the atomic cell 31, the light receiving element 32, a first holding member 33, a second holding member 34, a first atomic cell container 35, a second atomic cell container 36, the first temperature control element 37a, the second temperature control element 37b, the first temperature detection element 38a, and the second temperature detection element 38b.

As shown in FIG. 4, the atomic cell 31 has a first chamber 112, a second chamber 114, and a passage 116, through which the light emitted from the light emitting element 12 passes.

The first chamber 112 contains alkali metal atoms in a gas state. The first chamber 112 has a first space 102 and a first wall 122 defining the first space 102. The alkali metal atoms in a gas state are present in the first space 102. The first wall 122 has a first window 122a and a second window 122b through which the light emitted from the light emitting element 12 passes. The light emitted from the light emitting element 12 is incident on the first chamber 112 from the first window 122a, and emitted from the second window 122b. In the illustrated example, the first window 122a is a part of the X axis−side of the first wall 122. The second window 122b is a part of the X axis+side of the first wall 122.

The second chamber 114 contains alkali metal atoms M in a liquid state. Therefore, when the alkali metal atoms in a gas state contained in the first chamber 112 are reduced due to a reaction with the first wall 122 or the like, the liquid alkali metal atoms M are vaporized and a concentration of the alkali metal atoms in a gas state contained in the first chamber 112 can be kept constant. The second chamber 114 has a second space 104 and a second wall 124 defining the second space 104. In the illustrated example, the alkali metal atoms M in a liquid state are present in contact with the second wall 124 at a corner portion opposite to the first chamber 112 side of the second space 104. The second wall 124 has a lid portion 124a. In the illustrated example, the lid portion 124a is a part of the X axis+side of the second wall 124.

The passage 116 connects the first chamber 112 and the second chamber 114 to each other. The passage 116 is disposed between the first chamber 112 and the second chamber 114. The passage 116 has a third space 106 and a third wall 126 defining the third space 106. The third space 106 connects the first space 102 and the second space 104 to each other. The third wall 126 connects to the first wall 122 and the second wall 124 to each other. In the illustrated example, the third wall 126 is connected to the second window 122b of the first wall 122.

In the illustrated example, the shape of the inner wall surface of the first space 102, the second space 104, and the third space 106 is cylinder shape. The outer shape of the first wall 122, the second wall 124, and the third wall 126 is, for example, a cylinder shape. Therefore, as compared with the case where the outer shape of the walls 122, 124, and 126 is a rectangular parallelepiped shape, for example, when the coil 39 is wound around the atomic cell 31, the coil 39 is hardly damaged. The material of the walls 122, 124 and 126 is, for example, a glass, more specifically an aluminosilicate glass.

A length along the X axis of the first space 102 of the first chamber 112 is, for example, 5 mm or more and 15 mm or less, and preferably 10 mm. A length along the X axis of the second space 104 of the second chamber 114 is, for example, 2 mm or more and 8mm or less, and preferably 5 mm. A length along the X axis of the third space 106 of the passage 116 is, for example, 1 mm or more and 4 mm or less, and preferably 2 mm. Note that in the present specification, a “length along an axis of a space” of a chamber means a distance between two inner wall surfaces defining the space of the chamber or extended surfaces of the inner wall surface, intersecting a certain virtual axis.

In a direction orthogonal to a direction in which the light emitting element 12 and the light receiving element 32 are lined up, a length W1 of the first space 102 of the first chamber 112 and a length W2 of the second space 104 of the second chamber 114 are larger than a length W3 of the third space 106 of the passage 116.

The length W1 is a distance between two areas 2a and 2b of an inner surface 2 intersecting a first axis A1. The length W2 is a distance between two areas 4a and 4b of an inner surface 4 intersecting a second axis A2. The length W3 is a distance between two areas 6a and 6b of an inner surface 6 intersecting a third axis A3. The inner surface 2 is an inner surface of the first wall 122. The inner surface 4 is an inner surface of the second wall 124. The inner surface 6 is an inner surface of the third wall 126. The axes A1, A2, and A3 are axes along a direction orthogonal to an advancing direction of the light emitted from the light emitting element 12. The axes A1, A2 and A3 are parallel to each other.

In the illustrated example, the light emitting element 12 and the light receiving element 32 are disposed along the X axis, that is, X axis is an axis along the advancing direction of the light LL emitted from the light emitting element 12, and along the Y axis, in the illustrated example, the length W1 and the length W2 are larger than the length W3. The length W1 and the length W2 are, for example, the same. The length W1 and the length W2 are, for example, 3 mm or more and 10 mm or less, and preferably 5 mm. The length W3 is, for example, 1.5 mm or more and 2 mm or less. A length along the Y axis of the first wall 122 is, for example, 5 mm or more and 15 mm or less, and preferably 7 mm.

A gap portion 118 is provided between the first chamber 112 and the second chamber 114. In the illustrated example, the gap portion 118 is positioned on the Y axis+side of the passage 116.

As a manufacturing method of the atomic cell 31, for example, first, a first cylindrical member to be the first wall 122, a second cylindrical member to be the second wall 124, and a third cylindrical member to be the third wall 126 are prepared and connected to each other. Next, through holes are formed in the connected first, second, and third cylindrical members with a drill or the like. The through hole formed in the third cylindrical member becomes the third space 106. Next, a through hole is formed in the first cylindrical member from one side to form the first space 102, and a through hole is formed in the second cylindrical member from the other side to form the second space 104. Next, the first window 122a is connected to the first cylindrical member, and the lid portion 124a is connected to the second cylindrical member. The gap portion 118 is formed by the difference in diameter between the first cylindrical member and the second cylindrical member, and the third cylindrical member. In this manner, the atomic cell 31 can be manufactured.

The light receiving element 32 receives the light passing through the first chamber 112. The light receiving element 32 is disposed between the first chamber 112 and the second chamber 114. In the illustrated example, the light receiving element 32 is disposed in a part of the second wall 124 that defines the gap portion 118. The light receiving element 32 is electrically connected to the control unit 50. The light emitting element 12 is disposed on a side opposite to the light receiving element 32 with respect to the first chamber 112. In the illustrated example, the light emitting element 12 is disposed on the X axis−side of the first chamber 112, and the light receiving element 32 is disposed on the X axis +side of the first chamber 112.

The first holding member 33 and the second holding member 34 hold the atomic cell 31. The holding members 33 and 34 are disposed on an outer surface of the atomic cell 31. The thermal conductivity of a material forming the holding members 33 and 34 is higher than the thermal conductivity of a material forming the walls 122, 124, and 126 and the thermal conductivity of a material forming the first atomic cell container 35. A material of the holding members 33 and 34 is, for example, an aluminum, a titanium, a copper, a brass, or the like.

The first holding member 33 transmits a heat of a first temperature control element 37a to the alkali metal atoms in a gas state present in the first chamber 112. The temperature of the first holding member 33 is higher than the temperature of the second holding member 34. In the illustrated example, the first holding member 33 surrounds a part of the first wall 122, the third wall 126, and the second wall 124. The first holding member 33 is provided with a through hole 33a through which the light emitted from the light emitting element 12 passes.

The second holding member 34 transmits a heat of the second temperature control element 37b to the alkali metal atoms M in a liquid state present in the second chamber 114. The temperature of the second holding member 34 is lower than the temperature of the first holding member 33. The second holding member 34 is disposed apart from the first holding member 33. In the illustrated example, the second holding member 34 surrounds the second wall 124. Note that, although not shown, the holding members 33 and 34 may have heating wires wound around the atomic cell 31.

The atomic cell 31 has a body 130. The body 130 is a part of the atomic cell 31 positioned between two inner surfaces 8a and 8b having the largest distance among the inner surfaces 8 intersecting a fourth axis A4 along a direction in which the light LL emitted from the light emitting element 12 advances. In other words, it is the part of the atomic cell 31 excluding the walls at both ends along a direction in which the light LL advances. In the illustrated example, the axis A4 is parallel to the X axis.

The body 130 has a first part 132 on the side of the first chamber 112 and a second part 134 on the side of the second chamber 114. The first part 132 is a part in contact with the first holding member 33. The second part 134 is a part in contact with the second holding member 34. The first part 132 is, for example, a part surrounded by the first holding member 33 of the body 130. The second part 134 is, for example, an area surrounded by the second holding member 34 of the body 130. The temperature of the first part 132 is higher than the temperature of the second part 134. Note that the first holding member 33 and the second holding member 34, and the atomic cell 31 may not be in direct contact with each other. For example, an adhesive material or the like may be disposed between at least one of the first holding member 33 and the second holding member 34, and the atomic cell 31.

In the body 130, a length E1 along the X axis of the first part 132 is larger than the sum (D1+D3) of a length along the X axis of the first chamber 112 and a length along the X axis of the passage 116. In the body 130, a length E2 along the X axis of the second part 134 is smaller than the size D2 of the second chamber 114.

The first atomic cell container 35 contains the atomic cell 31, the light receiving element 32, and the holding members 33 and 34. The first atomic cell container 35 has a substantially rectangular parallelepiped outer shape. The first atomic cell container 35 is provided with a through hole 35a through which the light emitted from the light emitting element 12 passes. A material of the first atomic cell container 35 is, for example, the same as the material of the outer container 60. The first atomic cell container 35 can shield the magnetic field from the outside.

The first temperature control element 37a and the first temperature detection element 38a are disposed on the outer surface of the first atomic cell container 35, for example. In the illustrated example, the first temperature control element 37a and the first temperature detection element 38a are disposed on the outer surface of a part in contact with the first holding member 33 of the first atomic cell container 35. The first temperature control element 37a heats the first chamber 112 via the first atomic cell container 35 and the first holding member 33.

The second temperature control element 37b and the second temperature detection element 38b are disposed on the outer surface of the first atomic cell container 35. Specifically, the second temperature control element 37b and the second temperature detection element 38b are disposed on the outer surface of a part in contact with the second holding member 34 of the first atomic cell container 35. The second temperature control element 37b heats the second chamber 114 via the first atomic cell container 35 and the second holding member 34. Alternatively, the second temperature control element 37b, for example, dissipates the heat of the second chamber 114 to the outside via the first atomic cell container 35 and the second holding member 34, and cools the second chamber 114.

Note that the second temperature control element 37b and the second temperature detection element 38b may not be disposed. In this case, the second chamber 114 can be cooled by natural cooling.

The second atomic cell container 36 contains the first atomic cell container 35, the temperature control elements 37a and 37b, and the temperature detection elements 38a and 38b. The second atomic cell container 36 is provided with a through hole 36a through which the light emitted from the light emitting element 12 passes. A material of the second atomic cell container 36 is, for example, the same as the material of the first atomic cell container 35. The second atomic cell container 36 can shield the magnetic field from the outside. The first atomic cell container 35 and the second atomic cell container 36 are disposed, for example, apart from each other. Therefore, compared with a case where, for example, the first atomic cell container 35 and the second atomic cell container 36 are in contact with each other, a function of shielding the magnetic field from the outside can be enhanced.

The atomic oscillator 100 has, for example, the following effects.

The atomic oscillator 100 includes the light emitting element 12 that emits a light, an atomic cell 31 that has the first chamber 112 in which the alkali metal atoms in a gas state are contained and through which the light emitted from the light emitting element 12 passes, the second chamber 114 containing the alkali metal atoms Min a liquid state, and the passage 116 connecting the first chamber 112 and the second chamber 114 to each other, and a light receiving element 32 that receives the light passing through the first chamber 112, in which the light receiving element 32 is disposed between the first chamber 112 and the second chamber 114.

Therefore, in the atomic oscillator 100, the light emitted from the light emitting element 12 advances through the first chamber 112 toward the second chamber 114, and the light receiving element 32 disposed between the first chamber 112 and the second chamber 114 is the end point of an optical path of the light emitted from the light emitting element 12. When the first chamber 112 and the second chamber 114 are lined up in a direction orthogonal to the optical path, there is a possibility that the temperature of one of the first chamber 112 and the second chamber 114 affects the other of the first chamber 112 and the second chamber 114 along the optical path. In contrast to this, in the atomic oscillator 100, since the first chamber 112 and the second chamber 114 are adjacent at the end point of the optical path, the influence of one side temperature along the optical path to the other side temperature can be reduced. Therefore, it is possible to easily realize a configuration in which the temperature of one of the first chamber 112 and the second chamber 114 is hardly affected by the other. As a result, it is possible to easily control the state of the alkali metal atoms contained in the atomic cell 31.

Further, in the atomic oscillator 100, since the influence of the temperature of one of the first chamber 112 and the second chamber 114 on the other temperature is small, for example, without changing the length along the X axis of the first chamber 112, that is, without changing the optical path length in the first chamber 112, it is easy to change other parts of the atomic cell 31, for example, a distance between the first chamber 112 and the second chamber 114 and a length along the X axis of the second chamber 114. Therefore, even if the size of a part of the atomic cell 31 is changed, the influence on the accuracy of the oscillation frequency of the atomic oscillator 100 can be reduced as compared with the case where the size is changed in the atomic cell in which the first chamber 112 and the second chamber 114 are lined up in a direction orthogonal to the optical path.

Further, in the atomic oscillator 100, the optical path length in the first chamber 112 can be easily changed in a state in which the temperature of one of the first chamber 112 and the second chamber 114 is difficult to influence the other. For example, if the optical path length in the first chamber 112 is large, a reaction time between the light emitted from the light emitting element 12 and the alkali metal atoms becomes long, and the accuracy of the oscillation frequency of the atomic oscillator 100 can be increased.

As described above, in the atomic oscillator 100, since the size of a part of the atomic cell 31 can be easily changed, it is possible to easily increase variations of the product.

Furthermore, in the atomic oscillator 100, a distance between the first window 122a of the first wall 122 and the second chamber 114 can be increased as compared to the case where the first chamber 112 and the second chamber 114 are disposed in a direction orthogonal to the optical path. Therefore, it is difficult for the alkali metal atoms to be precipitated in the first window 122a by the temperature of the second chamber 114, and the oscillation characteristics of the atomic oscillator 100 can be stabilized. Note that since the second window 122b is in the side from which the light is emitted from the first chamber 112, even if the alkali metal atoms are precipitated in the second window 122b due to the temperature of the second chamber 114, the oscillation frequency of the atomic oscillator 100 is not influenced as compared with the case where the alkali metal atoms are precipitated in the first window 122a.

In the body 130 of the atomic oscillator 100, a length El along the X axis of the first part 132 is larger than the sum (D1+D3) of a length along the X axis of the first chamber 112 and a length along the X axis of the passage 116, and a length E2 along the X axis of the second part 134 is smaller than a length D2 along the X axis of the second chamber 114. Therefore, in the atomic oscillator 100, for example, as compared with the case where the length E2 in the body is larger than the sum of the lengths along the X axis between the second chamber and the passage, a temperature gradient is less likely to occur in the first chamber 112. Therefore, the oscillator frequency variation of the atomic oscillator 100 is small. For example, when the temperature gradient occurs in the first chamber 112, a light having various temperature dependencies is detected, and the variation in the oscillation frequency increases.

In the atomic oscillator 100, the first chamber 112 has the second window 122b through which the light emitted from the light emitting element 12 passes, and the third wall 126 is connected to the second window 122b. Therefore, in the atomic oscillator 100, the first chamber 112 and the second chamber 114 can be disposed in a line up manner, with a structure simpler than in the case where the passage 116 is connected to a part other than the second window 122b of the first chamber 112, in a direction in which the light emitting element 12 and the light receiving element 32 are lined up.

In the atomic oscillator 100, a distance W1 between the areas 2a and 2b of the first chamber 112 and a distance W2 between two areas 4a and 4b of the second chamber 114 are larger than the distance W3 between the two areas 6a and 6b. Therefore, in the atomic oscillator 100, for example, as compared with the case where the distances W2 and W3 are the same, it is difficult for the alkali metal atoms M in a liquid state to enter the first chamber 112.

1.2. Modification Example of Atomic Oscillator

1.2.1. First Modification Example

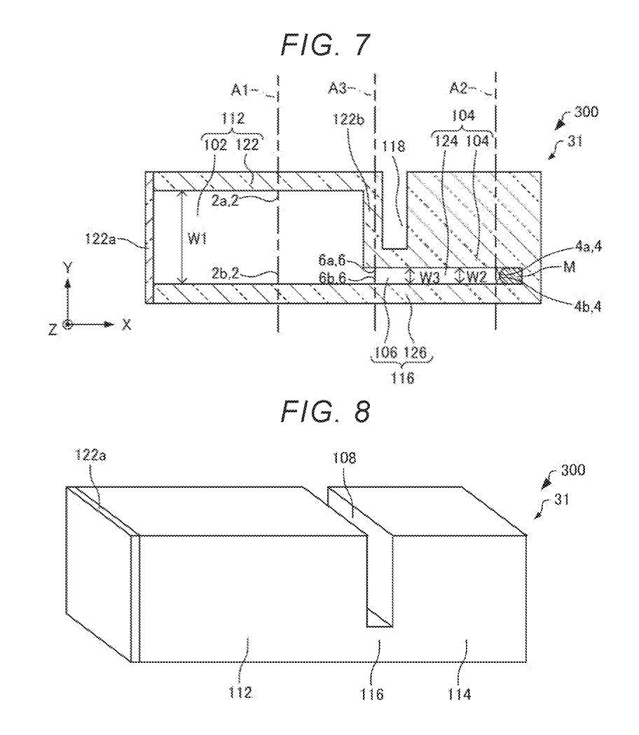

Next, an atomic oscillator 200 according to a modification example of the first embodiment will be described with reference to the drawings. FIG. 6 is a cross-sectional view schematically showing an atomic cell unit 30 of the atomic oscillator 200 according to the first modification example of the first embodiment. Note that in FIG. 6 and FIG. 7 to be described later, X, Y, and Z axes are shown as three axes orthogonal to each other.

Hereinafter, in the atomic oscillator 200 according to the first modification example of the first embodiment, differences from the example of the atomic oscillator 100 according to the above-described first embodiment will be described, and description of similar points will be omitted. This is the same in atomic oscillators according to a second modification example of the first embodiment described later.

In the atomic oscillator 100 described above, as shown in FIG. 4, in the body 130, the length E1 along the X axis of the first part 132 is larger than the sum (D1+D3) of the length along the X axis of the first chamber 112 and the length along the X axis of the passage 116. Further, in the body 130, the length E2 along the X axis of the second part 134 is smaller than the length D2 along the X axis of the second chamber 114.

In contrast to this, in the atomic oscillator 200, as shown in FIG. 6, in the body 130, the length E1 along the X axis of the first part 132 is smaller than the length Dl along the X axis of the first chamber 112. Further, in the body 130, a length E2 along the X axis of the second part 134 is larger than the sum (D2+D3) of a length along the X axis of the second chamber 114 and a length along the X axis of the passage 116.

In the body 130 of the atomic oscillator 200, a length E1 along the X axis of the first part 132 is smaller than a length Dl along the X axis of the first chamber 112, and a length E2 along the X axis of the second part 134 is larger than the sum (D2+D3) of the length along the X axis of the second chamber 114 and the length along the X axis of the passage 116. Therefore, in the atomic oscillator 200, it is possible to lower the temperature of the light receiving element 32 as compared with the case where the length E1 in the body is larger than the sum of the length along the X axis between the first chamber and the passage. Therefore, in the atomic oscillator 200, the noise of the light receiving element 32 can be reduced.

1.2.2. Second Modification Example

Next, an atomic oscillator 300 according to a second modification example of the first embodiment will be described with reference to the drawings. FIG. 7 is a cross-sectional view schematically showing the atomic cell 31 of the atomic oscillator 300 according to the second modification example of the first embodiment. FIG. 8 is a perspective view schematically showing the atomic cell 31 of the atomic oscillator 300 according to the second modification example of the first embodiment.

In the atomic oscillator 100 described above, as shown in FIG. 4, the distance W1 between the areas 2a and 2b of the first chamber 112 and the distance W2 between the two areas 4a and 4b of the second chamber 114 are larger than the distance W3 between the two areas 6a and 6b. Further, in the atomic oscillator 100, as shown in FIG. 5, the outer shape of the walls 122, 124, and 126 is a cylinder shape.

In contrast to this, in the atomic oscillator 300, as shown in FIG. 7, a distance W1 between two areas 2a and 2b of the first chamber 112 is larger than a distance W2 between two areas 4a and 4b of the second chamber 114. The distance W2 between the two areas 4a and 4b of the second chamber 114 is the same as the distance W3 between the two areas 6a and 6b of the passage 116. Further, in the atomic oscillator 300, as shown in FIG. 8, the outer shape of the walls 122, 124, and 126 is a rectangular parallelepiped shape.

Regarding a manufacturing method of the atomic cell 31, for example, firstly, rectangular parallelepiped members to be the walls 122, 124, and 126 are prepared, and a gap portion 118 is formed by cutting, etching, or the like. Next, a through hole is formed from one side of the rectangular parallelepiped member with a drill or the like to form a third space 106 and a second space 104. Next, a through hole is formed from one side of the rectangular parallelepiped member to form a first space 102. Next, the window 122a is connected to the rectangular parallelepiped member. In this manner, the atomic cell 31 can be manufactured.

In the atomic oscillator 300, a distance W1 between two areas 2a and 2b of the first chamber 112 is larger than a distance W2 between two areas 4a and 4b of the second chamber 114, and the distance W2 between the two areas 4a and 4b of the second chamber 114 is the same as a distance W3 between two areas 6a and 6b of the passage 116. Therefore, for example, the number of times of forming a through hole with a drill or the like can be reduced as compared with the case where the distance W2 is larger than the distance W3. Further, processing of separately forming a lid portion for sealing the third space 106 can be omitted.

The combination of the shape of the second chamber 114 and the outer shape of the atomic cell 31 is not limited to the combination of the first embodiment and the present embodiment, and the combination is arbitrary. For example, the outer shape of the atomic cell 31 in which the distance W2 of the second chamber 114 is larger than the distance W3 of the passage 116 may be a rectangular parallelepiped shape. The outer shape of the atomic cell 31 in which the distance W2 of the second chamber 114 is the same as the distance W3 of the passage 116 may be a cylindrical shape.

Further, the shape of the second chamber 114 and the outer shape of the atomic cell 31 can be arbitrarily combined with any of the above-described embodiments and modifications, and any of the embodiments and modifications described later.

2. Second Embodiment

2.1. Atomic Oscillator

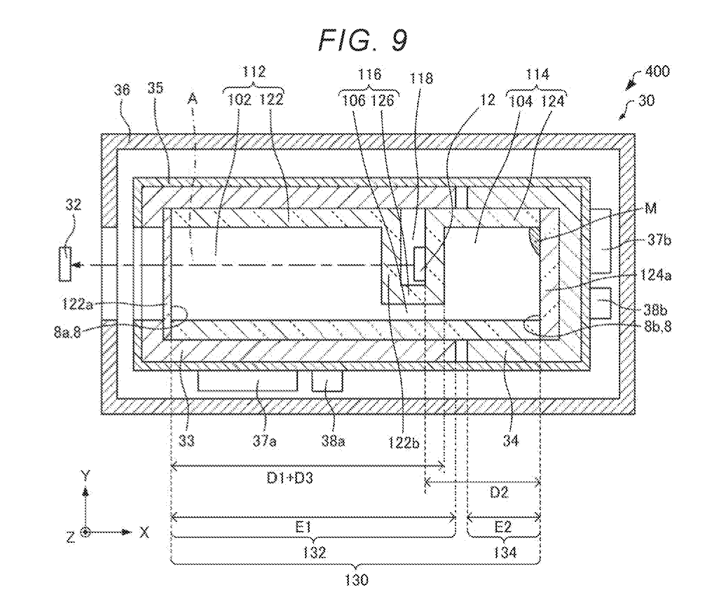

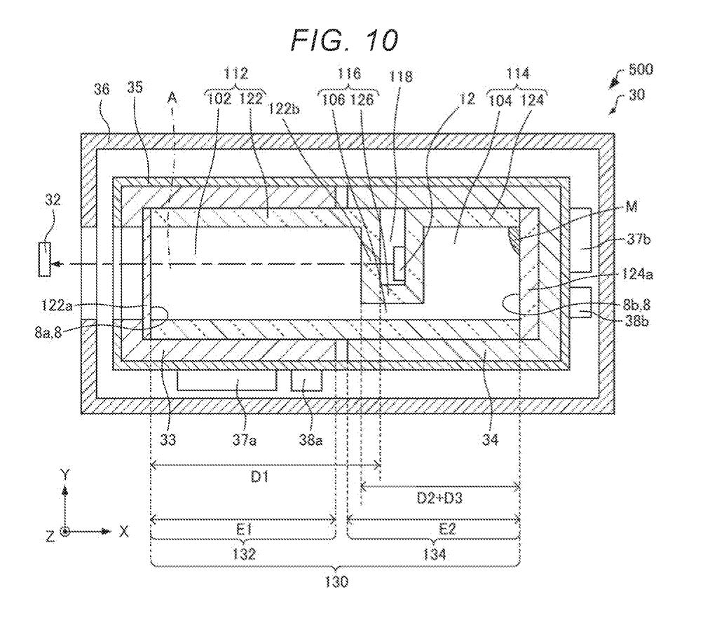

Next, an atomic oscillator 400 according to a second embodiment will be described with reference to the drawings. FIG. 9 is a cross-sectional view schematically showing an atomic cell unit 30 of the atomic oscillator 400 according to a second embodiment. Note that in FIG. 9 and FIG. 10 to be described later, X, Y, and Z axes are shown as three axes orthogonal to each other.

Hereinafter, in the atomic oscillator 400 according to the second embodiment, differences from the example of the atomic oscillator 100 according to the above-described first embodiment will be described, and description of similar points will be omitted.

In the atomic oscillator 100 described above, as shown in FIG. 4, the light receiving element 32 is disposed between the first chamber 112 and the second chamber 114.

In contrast to this, in the atomic oscillator 400, as shown in FIG. 9, the light emitting element 12 is disposed between the first chamber 112 and the second chamber 114. The light receiving element 32 is disposed on a side opposite to the light emitting element 12 with respect to the first chamber 112. The light receiving element 32 is supported by, for example, a supporting portion (not shown).

Note that, although not shown, an optical element may be disposed between the light emitting element 12 and the first chamber 112.

The atomic oscillator 400 has, for example, the following effects.

In the atomic oscillator 400, the light emitted from the light emitting element 12 advances through the first chamber 112 toward a side opposite to the side of the second chamber 114, and the light emitting element 12 is disposed between the first chamber 112 and the second chamber 114. Therefore, in the atomic oscillator 400, the light emitting element 12 disposed between the first chamber 112 and the second chamber 114 is the starting point of the optical path. Therefore, in the atomic oscillator 400, like the atomic oscillator 100, it is possible to easily realize a configuration in which the temperature of one of the first chamber 112 and the second chamber 114 is hardly influenced by the other.

2.2. Modification Example of Atomic Oscillator

Next, an atomic oscillator 500 according to a modification example of the second embodiment will be described with reference to the drawings. FIG. 10 is a cross-sectional view schematically showing an atomic cell unit 30 of the atomic oscillator 500 according to the modification example of the second embodiment.

Hereinafter, in the atomic oscillator 500 according to the modification example of the second embodiment, differences from the example of the atomic oscillator 400 according to the above-described second embodiment will be described, and description of similar points will be omitted.

In the atomic oscillator 400 described above, as shown in FIG. 9, in the body 130, the length E1 along the X axis of the first part 132 is larger than the sum (D1+D3) of the length along the X axis of the first chamber 112 and the length along the X axis of the passage 116. Further, in the body 130, the length E2 along the X axis of the second part 134 is smaller than the length D2 along the X axis of the second chamber 114.

In contrast to this, in the atomic oscillator 500, as shown in FIG. 10, in the body 130, the length E1 along the X axis of the first part 132 is smaller than the length D1 along the X axis of the first chamber 112. Further, in the body 130, a length E2 along the X axis of the second part 134 is larger than the sum (D2+D3) of a length along the X axis of the second chamber 114 and a length along the X axis of the passage 116.

In the body 130 of the atomic oscillator 500, a length E1 along the X axis of the first part 132 is smaller than a length D1 along the X axis of the first chamber 112, and a length E2 along the X axis of the second part 134 is larger than the sum (D2+D3) of the length along the X axis of the second chamber 114 and the length along the X axis of the passage 116. Therefore, in the atomic oscillator 500, it is possible to lower the temperature of the light emitting element 12 as compared with the case where the length E1 in the body is larger than the sum of the length along the X axis between the first chamber and the passage. Therefore, in the atomic oscillator 500, the lifetime of the light emitting element 12 can be increased.

In the atomic oscillator 500, the second temperature control element 37b can be used as the Peltier element 11 shown in FIG. 1. Further, the second temperature detection element 38b can be used as the temperature sensor 13 shown in FIG. 1. Therefore, in the atomic oscillator 500, the number of components can be reduced.

3. Third Embodiment

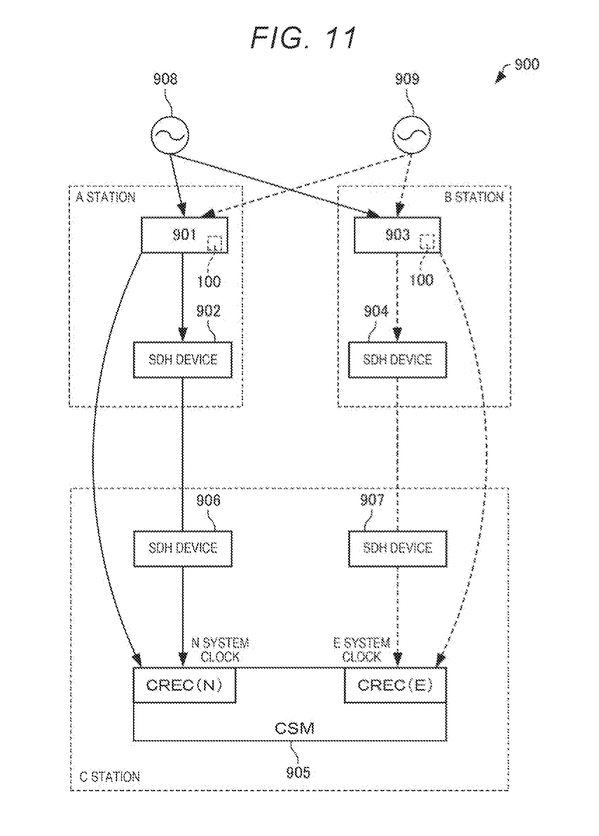

Next, a frequency signal generation system according to a third embodiment will be described with reference to the drawings. The following clock transmission system as a timing server is an example of a frequency signal generation system. FIG. 11 is a schematic configuration diagram showing the clock transmission system 900.

The clock transmission system according to the present disclosure includes the atomic oscillator according to the present disclosure. In the following, the clock transmission system 900 including the atomic oscillator 100 will be described as an example.

The clock transmission system 900 is to synchronize a clock of each device in a time division multiplexing network, and is a system having a redundant configuration of a normal (N) system and an emergency (E) system.

As shown in FIG. 11, the clock transmission system 900 includes a clock supply device 901 and a synchronous digital hierarchy (SDH) device 902 of an A station (upper level (N system)), a clock supply device 903 and SDH device 904 of a B station (upper level (E system)), and a clock supply device 905 and SDH devices 906 and 907 of a C station (lower level). The clock supply device 901 has the atomic oscillator 100 and generates a N system clock signal. The atomic oscillator 100 in the clock supply device 901 generates a clock signal in synchronization with a more accurate clock signal from master clocks 908 and 909 including the atomic oscillator using a cesium.

Based on the clock signal from the clock supply device 901, the SDH device 902 transmits and receives a main signal, superimposes the N system clock signal on the main signal, and transmits the signal to the lower level clock supply device 905. The clock supply device 903 has the atomic oscillator 100 and generates a E system clock signal. The atomic oscillator 100 in the clock supply device 903 generates a clock signal in synchronization with a more accurate clock signal from master clocks 908 and 909 including the atomic oscillator using a cesium.

Based on the clock signal from the clock supply device 903, the SDH device 904 transmits and receives a main signal, superimposes the E system clock signal on the main signal, and transmits the signal to the lower level clock supply device 905. The clock supply device 905 receives the clock signal from the clock supply devices 901 and 903, and generates a clock signal in synchronization with the received clock signal.

The clock supply device 905 normally generates a clock signal in synchronization with the N system clock signal from the clock supply device 901. Then, when an abnormality occurs in the N system, the clock supply device 905 generates a clock signal in synchronization with the E system clock signal from the clock supply device 903. By switching from the N system to the E system like this, a stable clock supply can be guaranteed, and the reliability of the clock path network can be enhanced. The SDH device 906 transmits and receives the main signal based on the clock signal from the clock supply device 905. Similarly, the SDH device 907 transmits and receives the main signal based on the clock signal from the clock supply device 905. In this way, it is possible to synchronize the device of the station C with the device of the station A or the station B.

The frequency signal generation system according to the third embodiment is not limited to the clock transmission system. The frequency signal generation system is equipped with the atomic oscillator, and includes various devices using the frequency signal of the atomic oscillator and a system configured with a plurality of devices. The frequency signal generation system includes a terminal to which a frequency signal from the atomic oscillator is input and a controller to control the atomic oscillator.

The frequency signal generation system according to the third embodiment may be, for example, a smart phone, a tablet terminal, a timepiece, a portable phone, a digital still camera, a liquid ejecting apparatus such as an ink jet printer, a personal computer, a television, a video camera, a video tape recorder, a car navigation device, a pager, an electronic notebook, an electronic dictionary, a calculator, an electronic game machine, a word processor, a workstation, a video phone, a security television monitor, an electronic binoculars, a point of sales (POS) terminal, a medical machine, a fish finder, a global navigation satellite system (GNSS) frequency standard, various measuring machines, instruments, a flight simulator, a terrestrial digital broadcasting system, a portable phone base station, and a moving object.

Examples of the medical machine include, for example, an electronic clinical thermometer, a blood pressure manometer, a blood glucose meter, an electrocardiogram measurement device, an ultrasonic diagnostic device, an electronic endoscope, and a magnetocardiograph. Examples of the instruments include, for example, instruments such as a vehicle, an aircraft, and a ship. Examples of the moving object include, for example, a vehicle, an aircraft, a ship, or the like.

The present disclosure may omit a part of the configuration within a range having the features and effects described in this application, or combine each embodiment and modification.

The present disclosure includes a configuration (for example, a configuration having the same function, a method, and a result, or a configuration having the same object and effect) that is substantially the same as the configuration described in the embodiment. Further, the present disclosure includes a configuration in which non-essential parts of the configuration described in the embodiments are replaced. Further, the present disclosure includes a configuration that achieves the same operation and effect as the configuration described in the embodiments, or a configuration that can achieve the same object. Further, the present disclosure includes a configuration in which a known technique is added to the configuration described in the embodiments.

What is claimed is:

1. An atomic oscillator comprising:
a light emitting element;
an atomic cell including a first chamber in which alkali metal atoms in a gas state are contained and through which a light from the light emitting element passes, a second chamber in which alkali metal atoms in a liquid state are contained, and a passage connecting the first chamber and the second chamber to each other; and
a light receiving element that receives the light passing through the first chamber, wherein the light receiving element is disposed between the first chamber and the second chamber.

2. The atomic oscillator according to claim 1, wherein the light emitting element is disposed on aside opposite to the light receiving element with respect to the first chamber.

3. An atomic oscillator comprising:
a light emitting element;
an atomic cell including a first chamber in which alkali metal atoms in a gas state are contained and through which a light from the light emitting element passes, a second chamber in which alkali metal atoms in a liquid state are contained, and a passage connecting the first chamber and the second chamber to each other; and
a light receiving element that receives the light passing through the first chamber, wherein the light emitting element is disposed between the first chamber and the second chamber.

4. The atomic oscillator according to claim 3, wherein the light receiving element is disposed on a side opposite to the light emitting element with respect to the first chamber.

5. The atomic oscillator according to claim 1, further comprising:
a first holding member that holds the atomic cell, second holding member that holds the atomic cell, the second holding member having a temperature lower than a temperature of the first holding member, wherein a part of the atomic cell between two inner surfaces of the atomic cell having a first part that is in contact with the first holding member, and a second part that is in contact with the second holding member, among inner surfaces intersecting an axis along which the light from the light emitting element advances, the part of the atomic cell having the longest distance between the two inner surfaces along the axis, and in the part of the atomic cell, E1>(D1+D3) and E2<D2, where E1 is a length of the first part along the axis, E2 is a length of the second part along the axis, D1 is a length of the first chamber along the axis, D2 is a length of the second chamber along the axis, and D3 is a length of the passage along the axis.

6. The atomic oscillator according to claim 1, further comprising:
a first holding member that holds the atomic cell, a second holding member that holds the atomic cell, the second holding member having a temperature lower than a temperature of the first holding member, wherein a part of the atomic cell between two inner surfaces of the atomic cell having a first part that is in contact with the first holding member, and a second part that is in contact with the second holding member, among inner surfaces intersecting an axis along which the light from the light emitting element advances, the part of the atomic cell having the longest distance between the two inner surfaces along the axis, and in the part of the atomic cell, E1<D1 and E2>(D2+D3), where E1 is a length of the first part along the axis, E2 is a length of the second part along the axis, D1 is a length of the first chamber along the axis, D2 is a length of the second chamber along the axis, and D3 is a length of the passage along the axis.

7. The atomic oscillator according to claim 1, wherein the first chamber has a window through which the light from the light emitting element passes, and the passage is connected to the window.

8. The atomic oscillator according to claim 1, wherein W1>W3 and W2>W3, where W1 is a distance between two areas of an inner surface in the first chamber, the two areas intersecting a first axis orthogonal to a direction in which the light from the light emitting element advances, W2 is a distance between two areas of an inner surface in the second chamber, the two areas intersecting a second axis parallel to the first axis, and W3 is a distance between two areas of an inner surface in the passage, the two areas intersecting a third axis parallel to the first axis.

9. The atomic oscillator according to claim 1, wherein W1>W2 and W2=W3, where W1 is a distance between two areas of an inner surface in the first chamber, the two areas intersecting a first axis orthogonal to a direction in which the light emitted from the light emitting element advances, W2 is a distance between two areas of an inner surface in the second chamber, the two areas intersecting a second axis parallel to the first axis, and W3 is a distance between two areas of an inner surface in the passage, the two areas intersecting a third axis parallel to the first axis.

10. A frequency signal generation system comprising:
an atomic oscillator including a light emitting element, an atomic cell including a first chamber in which alkali metal atoms in a gas state are contained and through which a light from the light emitting element passes, a second chamber in which alkali metal atoms in a liquid state are contained, and a passage connecting the first chamber and the second chamber to each other, and a light receiving element that receives the light passing through the first chamber, wherein one of the light receiving element and the light emitting element is disposed between the first chamber and the second chamber.
